(19) United States
(12) Patent Application Publication
(10) Pub. No.: US 2010/0241375 A1
(43) Pub. Date: Sep. 23, 2010

(54) SMART DEVICE FOR ENABLING REAL-TIME MONITORING, MEASURING, MANAGING AND REPORTING OF ENERGY BY SOLAR PANELS AND METHOD THEREFORE

(75) Inventors: Sudesh Kumar, North Las Vegas, NV (US); PramodKumar Maganlal Patel, San Diego, CA (US); DilipKumar Khana Bhana, Cordova, TN (US)

Correspondence Address: IPxLAW Group LLP, 95 South Market Street, Suite 570, San Jose, CA, 95113, US

(73) Assignee: SOLAR SIMPLIFIED LLC, San Diego, CA (US)

(21) Appl. No.: 12/730,012

(22) Filed: Mar. 23, 2010

Related U.S. Application Data
(60) Provisional application No. 61/162,593, filed on Mar. 23, 2009.

(51) Int. Cl. G01R 21/133; G06F 19/00

(52) U.S. Cl. 702/62

(57) ABSTRACT

A solar panel monitoring device and method is disclosed. The solar panel monitoring smart device comprises at least one power source or input; at least one sensor connected to the input, where the at least one sensor is adapted to responsively generate monitoring information on the input with which it is associated; a processor for receiving the monitoring information regarding the input from each of the sensors, and adapted to forward the received monitoring information; and a transmission chip for receiving the monitoring information, packetizing the monitoring information, and transmitting to a remote location.

### CROSS-REFERENCED TO RELATED APPLICATIONS

This application claims priority to U.S. Provisional Patent Application No. 61/162,593, filed 23 Mar. 2009, entitled SMART DEVICE FOR ENABLING REAL-TIME —MONITORING, MEASURING, MANAGING AND REPORTING OF ENERGY BY SOLAR PANELS AND METHOD THEREFORE, by Sudesh Kumar, PramodKumar Maganlal Patel, and DilipKumar Khana Bhana, the disclosure of which is incorporated herein by reference as though set forth in full.

### FIELD OF THE INVENTION

The invention relates to monitoring sources of power generation, and, more specifically, to real-time monitoring and reporting of information relating to the power generation and status of solar panel installations.

### DESCRIPTION OF THE PRIOR ART

In the past decade, the global solar industry has grown by up to 30-40 percent, or even more, annually. In the next 5 years, the solar industry will experience double-digit growth. It is expected that, world-wide, billions of solar panels will be installed, up from 38 million in 2009. With the increasing rate of solar panel deployment, manufacturing costs have decreased, making installation and operation of solar panels more affordable. As the price for installing and operating solar panels decreases, technology will inevitably become a viable competitor for producing and supplying affordable electricity to homes and businesses alike.

Solar panels are generally dumb, passive devices housing active photovoltaic solar cells. Most home-installed solar panels are less than 15% efficient, and the latest solar panels currently on the market are up to 25% efficient in ideal conditions. One form of solar panels, which is establishing great notoriety, is Photo voltaic (PV). In the year 2006, the 40% efficiency barrier was surpassed, and while many laboratories and companies continue to improve on solar cell technology, high-efficiency cells are still not commercially available. With a realized efficiency of only up to 25% in ideal conditions, it is crucial to pro-actively monitor, measure and manage the solar panels, in order to prevent problems from occurring, and to maximize the operational efficiency and electricity generated in both the short- and long-term.

While some solar panel monitoring devices do currently exist, these devices are inadequate. Such devices are often after-market piecemeal, and fail to offer a comprehensive solution at the panel level that offers the information logging capability and control necessary for operating a solar panel installation and maintaining peak performance over time. These devices do not provide real-time feedback and monitoring, two-way communication, or monitoring when the photovoltaic cells of the solar panel are inactive. Further, while the lack of control in the prior art devices may suffice for small installations, the need for intelligent monitoring and control increases with the size of the solar panel installation.

Accordingly, what is needed is an integrated device for real-time monitoring, measuring, managing and reporting the status and output of a solar panel. The device should report, in real-time, the voltage, current, temperature and location of the panel, as well as immediately report any adverse status conditions requiring immediate attention, for logging and review off-site.

### SUMMARY OF THE INVENTION

In accordance with an embodiment of the present invention, a device for real-time monitoring and reporting the status and output of a solar panel is provided. The device may be installed in the junction box of a solar panel or as an external mounted device, and provides a comprehensive solution for an “intelligent” solar panel.

In another embodiment of the present invention, a device and method are provided for real-time reporting of characteristics such as voltage, current, and temperature to a centralized server for monitoring.

In yet another embodiment of the present invention, a method is provided for reporting adverse events, which may negatively and immediately impact solar panel performance.

In an alternative embodiment, a device and method are provided for monitoring and logging the real-time and historical performance characteristics of solar panels for alerting of any necessary maintenance, routine or otherwise, of the panel that may be necessary.

In still another embodiment of the present invention, a device and method are provided for monitoring and logging the geographic location of a solar panel installation.

In another embodiment of the present invention, a device and method are provided for monitoring the health status of a solar panel, its physical integrity, its geographic location, and any other adverse events, even if its photovoltaic cells are inactive and no current is being generated.

Another embodiment of the present invention provides a device and method for controlling a remotely installed solar panel.

Yet another embodiment of the present invention provides a device and method for bypassing and isolating a defective solar panel.

### BRIEF DESCRIPTION OF THE DRAWINGS

FIG. 1 shows a printed circuit board assembly in accordance with an embodiment of the present invention.

FIG. 2 shows a flow diagram of the process of solar panel information collection and reporting in accordance with a method of the present invention.

FIG. 3 shows a network map of how an embodiment of the present invention uses the Internet to deliver solar panel status information.

FIG. 4 shows a flow diagram of the high-level blocks of the present invention shown in communication with each other, in accordance with an embodiment of the present invention.

### DESCRIPTION OF THE PREFERRED EMBODIMENTS

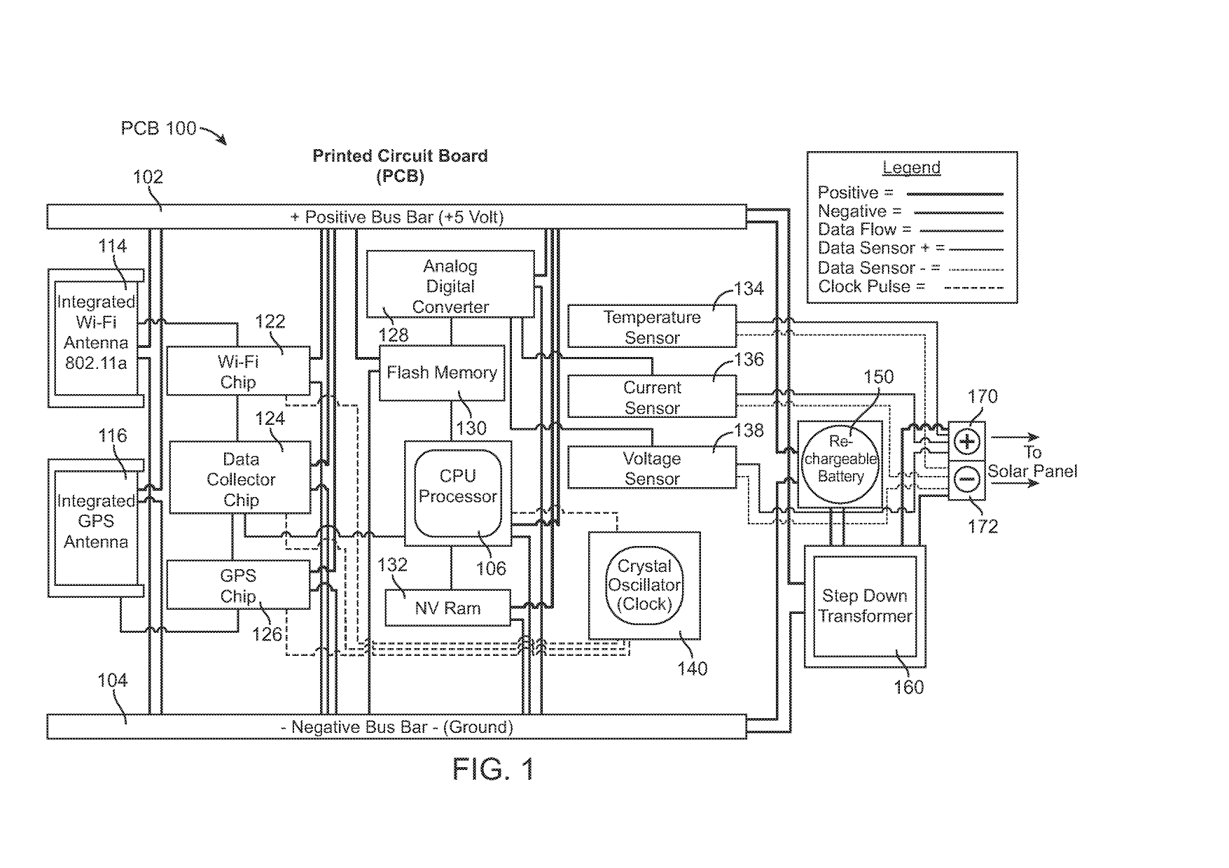

In reference to FIGS. 1 through 4, a device and method for comprehensively monitoring and reporting, in real-time, the health status and output of a solar panel are disclosed, in accordance with various apparatus and methods of the present invention. The device generally includes a processor, random access memory (RAM), one or more sensors, a battery, and a wireless network interface device. The device's sensors gather information relating to the electricity generated by the device, e.g., voltage, current, and/or power; environmental conditions, e.g., weather; device and/or solar panel status or health, e.g., electrical shorts; and geographic positioning. The processor receives the above information provided by the sensors and, through the network interface, continually transmits the information in real-time to a base station, server, or other computer system. Through the network interface, the processor is also configurable for receiving transmissions. Transmissions received by the processor may command a shutdown or bypass of the solar panel, reorientation of the solar according to positioning of the sun, or request further status or power generation information from the device.

Referring now to FIG. 1, a printed circuit board (PCB) assembly 100 for use as a solar panel monitoring (smart) device is shown, in accordance with an embodiment of the present invention. In accordance with one embodiment of the present invention, PCB assembly 100 is implemented by installing into the junction box of a solar panel, or the housing of a solar panel. In accordance with alternative embodiments of the present invention, PCB 100 is housed in its own enclosure which is attached by fasteners or adhesives to the back of to a solar panel.

In one embodiment of the present invention, PCB assembly 100 constitutes the solar panel monitoring device as a whole. In alternative embodiments of the present invention, PCB assembly 100, as shown, does not constitute the entire solar panel monitoring device. For example, in such cases, PCB assembly 100 may further include additional, external sensors. Such sensors may include, for example, an accelerometer, or a sensor for measuring atmospheric gas components.

Positive lead 170 and ground lead 172 are shown coupled to the power output of the solar panel in which the PCB assembly 100 is installed. In accordance with an embodiment of the present invention, positive lead 170 and negative lead 172 are the primary source of power to PCB assembly 100. Positive lead 170 is shown coupled to temperature sensor 134, current sensor 136, voltage sensor 138, and step down transformer 160. Ground lead 172 is also shown coupled to temperature sensor 134, current sensor 136, voltage sensor 138, and step down transformer 160.

Step down transformer 160 receives the power generated at the solar panel and steps it down to a voltage appropriate for the various electronics on PCB assembly 100, in accordance with an embodiment of the present invention. As shown in FIG. 1, step down transformer operates to output +5V. Step down transformer 160 is shown coupled to positive bus bar 102 and negative bus bar (ground) 104. Step down transformer 160 is also shown coupled to rechargeable battery 150. Step down transformer 160 supplies 5V to the rechargeable battery 150 and to positive bus bar 102. While the solar panel is generating current, rechargeable battery 150 may undergo charging, and current may be supplied to positive bus bar from the solar panel through step down transformer 160. In other words, when the solar panel in which the monitoring device of an embodiment of the present invention is installed is actively generating current, the rechargeable battery 150 is charged, and the components of PCB assembly 100 are powered by the output of step down transformer 160.

In accordance with an embodiment of the present invention, rechargeable battery 150 acts as the power source for PCB assembly 100 under certain circumstances. For example, when the solar panel in which the solar panel monitoring device is installed is in darkness, or is not generating current for any number reasons, PCB assembly 100 is powered by rechargeable battery 150. As way of further example, the solar panel may be broken, put into bypass mode (as will be discussed shortly), or may not be generating current sufficient for powering the monitoring device. In one embodiment of the present invention, battery 150 is ideally operative to power the PCB 100 of the solar panel to which it is attached for a full 12 hours.

In accordance with an embodiment of the present invention, it is important for the solar panel monitoring device to transmit solar panel status information even when the installed solar panel is not generating any electricity. Further, it may also be necessary for the solar panel to receive information requests and other commands from a remote server when the solar panel is not generating electricity. Rechargeable battery 150 ensures that the solar panel's monitoring device is always powered and remotely accessible. Rechargeable battery 150 is shown coupled to positive bus bar 102 and negative bus bar 104 (ground). Through bus bars 102 and 104, power is supplied to the PCB assembly 100 components by rechargeable battery 150 or step down transformer 160.

Positive bus bar 102 is shown coupled to rechargeable battery 150, step down transformer 160, WiFi antenna 114, Global Positioning System (GPS) antenna 116, WiFi chip 122, data collector chip 124, GPS chip 126, analog to digital converter (ADC) 128, flash memory 130, processor 106, and non-volatile random access memory (NVRAM) 132, in accordance with an embodiment of the present invention. Positive bus bar 102 generally supplies the antennas 114 and 116, chips 122, 124, 126, ADC 128, processor 106, and memories 130 and 132 with the operating voltage of +5V. As discussed previously, positive bus bar 102 is powered by either rechargeable battery 150, or by step down transformer 160.

As used herein “chip” refers to any integrated circuit, die, or semiconductor.

In accordance with an alternative embodiment of the present invention, positive bus bar 102 may be further coupled to temperature sensor 134, or other installed sensors, such as, for example an accelerometer. The operation and reporting of such sensors may or may not occur independently of whether the solar panel of the installed device is generating any electricity. For example, the operation of current sensor 136 and voltage sensor 138 are dependent upon the installed device's solar panel generating electricity for powering the sensor, and also for providing the input values. Other sensors may similarly depend upon the current output from the solar panel, and may be connected directly to leads 170 and 172 instead of positive bus bar 102 and ground 104. Conversely, in accordance with an alternative embodiment of the present invention, other sensors function independently of the solar panel's power generation, and report information even when the solar panel is not generating any electricity.

Still making reference to FIG. 1, negative bus bar 104, also referred to as ground 104, is shown coupled to rechargeable battery 150, step down transformer 160, WiFi antenna 114, GPS antenna 116, WiFi chip 122, data collector chip 124, GPS chip 126, ADC 128, flash memory 130, processor 106, and NVRAM 132. In one embodiment of the present invention, negative bus bar 104 serves as a ground for the antennas, chips, memories, processors, sensors, clocks, and any other devices installed on PCB assembly 100. In accordance with an alternative embodiment of the present invention, negative bus bar 104 is further coupled to temperature sensor 134 or other installed sensors, such as, for example an accelerometer. All devices and chips on the PCB assembly 100 may draw power from the positive bus bar 102, and drain out to negative bus bar 104. By using power directly from the solar panel, or power stored in rechargeable battery 150, the device of the present invention operates without needing any additional or external power sources.

In accordance with an embodiment of the present invention, flash memory 130 stores information provided from ADC 128, and is then read by processor 106. Flash memory 130 may be repeatedly overwritten by ADC 128, or flash memory may be erased by processor 106 after each read operation by processor 106. In FIG. 1, flash memory 130 is shown coupled to ADC 128, positive bus bar 102, and negative bus bar 104. In accordance with alternative embodiments of the present invention, PCT assembly 100 includes more than one flash memory 130; for example, it may be beneficial to have a flash memory for each of the sensors 134, 136, and 138, as well as any other sensors.

Data collector chip 124 generally stores digital data received from processor 106 and GPS chip 126, and then forwards the received data to WiFi chip 122. Data collector chip 124 is shown coupled to positive bus bar 102, negative bus bar 104, crystal oscillator 140, GPS chip 126, processor 106, and WiFi chip 122 in PCB assembly 100 of FIG. 1. Crystal oscillator 140 sends clock pulses to processor 106, WiFi chip 122, GPS chip 126 and to data collector chip 124, and then sequences the release of that data by data collector chip 124. Data collector chip 124 may be any known circuit that is capable of storing or saving information of the type generated by processor 106 and that is capable of forwarding the same to the WiFi chip 122.

In accordance with an embodiment of the present invention, GPS chip 126 identifies the global coordinates of the solar panel in which the monitoring device is installed. GPS chip 126, which functions as a location identifier, is shown coupled to GPS antenna 116, data collector chip 124, positive bus bar 102, negative bus bar 104, and crystal oscillator 140, on PCB assembly 100 of FIG. 1. GPS chip 126 is powered by positive bus bar 102 and ground 104. In one embodiment of the present invention, GPS chip 126 utilizes GPS antenna 116 to receive the GPS signals from satellites.

Crystal oscillator 140 times when GPS chip 126 determines the global coordinates of the solar panel in which it is installed, and forwards the determined value to data collector chip 124. In one embodiment of the present invention, exemplary hardware for use as GPS chip 126 may be, for example, the SiRFstar III chip manufactured SiRF Technology.

The positioning coordinates provided by GPS chip 126 have numerous uses. Because the present invention constantly reports, in real-time, solar panel power output, any unexpected and/or drastic change in power output may indicate a physical problem with the solar panel in which the monitoring device is installed. For example, a drop in current may indicate that the solar panel is in need of immediate service. In such a case, the GPS coordinates determined by GPS chip 126 allow a repairperson to rapidly locate the malfunctioning solar panel in a large industrial solar panel array containing thousands of panels. A repairperson can input the coordinates of the malfunctioning solar panel into his/her mobile GPS, and be immediately directed towards the malfunctioning solar panel.

Further, in the case of unexpected movement of a solar panel, for example due to theft, a change of coordinates reported by monitoring device will immediately trigger an alarm, either in monitoring software at a remote location, or a physical alarm at the site of the solar panel installation. With rechargeable battery 150 capable of supplying power to the devices on PCB assembly 100 even when the solar panel is no longer actively generating current, the monitoring device can continue to report the movement of the solar panel in which it is installed even while it's being transported.

In accordance with an embodiment of the present invention, integrated GPS antenna 116 is used by GPS chip 126 to receive GPS transmissions. Integrated GPS antenna 116 is shown coupled to positive bus bar 102, negative bus bar 104, and GPS chip 126 in PCB assembly 100 of FIG. 1. In some installations, integrated GPS antenna 116 is completely housed within the junction box of the solar panel in which PCB assembly 100 is installed. In other installations, integrated GPS antenna 116 is located, partially or fully, outside of the junction box to increase the integrity of the received GPS signal. In accordance with an embodiment of the present invention, exemplary hardware for use as GPS antenna 116 is, for example, the RADIONOVA M10290, manufactured by Antenova of Elgen, Ill.

Temperature sensor 134 is shown coupled to positive lead 170, ground lead 172, and ADC 128 of PCB assembly 100 of FIG. 1, in accordance with an embodiment of the present invention. In alternative embodiment of the present invention, temperature sensor 134 is coupled to positive bus bar 102 and negative bus bar 104 instead of to leads 170 and 172, respectively. Temperature sensor 134 measures the temperature of the solar panel in which PCB assembly 100 is installed, and responsively generates a signal proportionate to the temperature measured. The signal generated by temperature sensor 134 is then received by ADC 128, which converts the reading into a digital value. In accordance with an embodiment of the present invention, temperature sensor 134 may be, for example, a thermocouple.

Current sensor 136 measures the current being generated by the solar panel at any given moment. In FIG. 1, current sensor 136 is shown coupled to the positive lead 170 and ground lead 172, and leads 170 and 172 are directly coupled to the solar panel output. In this configuration, the current read by current sensor 136 will be the current coming directly out of the solar panel in which the monitoring device is installed. Current sensor 136 is also shown coupled to ADC 128. In accordance with an embodiment of the present invention, the current being output by the solar panel in which the device is installed is measured by current sensor 136 generating a signal responsive to the current output of the solar panel, which is then converted to a digital value by ADC 128. In one embodiment of the present invention, current sensor 136 is, for example, the current sensor model GRI CS-1, manufactured by George Risk Industries of Kimball, Nebr.

Voltage sensor 138 measures the voltage being generated by the solar panel at any given moment. Voltage sensor 138 is shown coupled to the positive lead 170 and ground lead 172, and leads 170 and 172 are directly coupled to the solar panel output. In such a configuration, the voltage read by voltage sensor 138 will be the voltage coming directly out of the solar panel in which the device is installed. Voltage sensor 138 is also shown coupled to ADC 128. In accordance with an embodiment of the present invention, the voltage of the solar panel may be measured by voltage sensor 138 generating a signal responsive to the voltage output of the solar panel, which is then converted to a digital value by ADC 128. In accordance with an embodiment of the present invention, voltage sensor 138 is, for example, voltage sensor model S-50-P117, manufactured by Phidgets Inc. of Calgary, Alberta, Canada.

In accordance with an embodiment of the present invention, WiFi chip 122 is operative to receive the data stored on data collector chip 124, and then packetize the received information. After information packets have been generated by WiFi chip 122, WiFi chip 122 wirelessly transmits the generated packets to a base station or other solar panel monitoring database or server. For example, WiFi chip 122 packetizes and transmits data related to solar panel temperature (from temperature sensor 134), the current being generated by the solar panel (from current sensor 136), the voltage coming out of the solar panel (from voltage sensor 138), and/or the GPS coordinates of the solar panel (from GPS chip 126).

In accordance with an embodiment of the present invention, WiFi chip 122 is not limited to packet transmission, and is operative to receive wireless communications sent from other solar panels, base stations, servers, or other monitoring or control entities.

In one embodiment of the present invention, WiFi chip 122 is in regular communication with an externally located 802.11x Access Point. Each 802.11x Access Point stores the signal strength level of each of the WiFi chip 122 with which it communicates. If the signal strength of a communicating WiFi chip 122 changes due to movement of panel or other reasons, then the 802.11x Access Point or WiFi Chip 122 can send an alarm to a central base station, server, or monitoring facility. It is noted that while “WiFi” chip is used herein, any type of wireless communication may be used including but not limited to “WiMAX”.

Referring still to FIG. 1, WiFi chip 122 is shown coupled to positive bus bar 102, negative bus bar 104, crystal oscillator 140, data collector chip 124, and WiFi antenna 114 of PCB assembly 100 of FIG. 1. In accordance with an embodiment of the present invention, WiFi chip 122 is powered by the current supplied from positive bus bar 102. Data collector chip 124 may be the source of the data to be packetized and transmitted by WiFi chip 122, or, in accordance with an alternative embodiment of the present invention, the data may arrive from the processor 106, or another device. Crystal oscillator 140 times when WiFi chip 122 is to receive, packetize, and/or transmit information, and also synchronizes WiFi chip 122′s activity with the other devices, chips, or sensors of PCB assembly 100.

WiFi chip 122 may use any promulgated wireless networking standard or other proprietary over-the-air modulation technique capable of secure transmission. Examples of such protocols are the 802.11 family, including 802.11b, 802.11g, 802.11n, and 802.11a. In accordance with an embodiment of the present invention, the 802.11a standard is selected as the operational standard for transmitting and receiving data by WiFi chip 122. In this respect, the WiFi chip 122 is capable of performing two-way communications with the access point 305. The 802.11a standard operates in the 5 GHz frequency band, freeing it from any interference from the many devices operating in the 2.4 GHz band. While 802.11a does not provide the greatest indoor range due to the high reflection of smaller wavelength transmissions, the 802.11a standard is an excellent choice for implementation in outdoor solar panel installations, where walls and other obstructions do not exist. In an alternative embodiment of the present invention, WiFi chip 122 is based upon the 802.11n standard, which allows for greater transmission range, and thus allows significantly more solar panel monitoring devices to share a single common access point. In one embodiment of the present invention, WiFi chip 122 is driven by an embedded Linux operating system, and supports DHCP, ARP, TCP/IP, UDP, HTTP, FTP and telnet protocols. In accordance with an embodiment of the present invention, WiFi chip 122 is, for example, the SLTC4560 by ST-Ericsson.

WiFi antenna 114 may be used by WiFi chip 122 to receive and transmit wireless data packets. WiFi antenna 114 is shown coupled to positive bus bar 102, negative bus bar 104, and WiFi chip 122 in PCB assembly 100 of FIG. 1. In accordance with an embodiment of the present invention, WiFi antenna 114 is powered by positive bus bar 102 and 104. In an alternative embodiment of the present invention, WiFi antenna 114 is powered through WiFi chip 122. WiFi antenna 114 may be completely housed within the junction box of the solar panel in which PCB assembly 100 is installed, or it may be located, partially or fully, outside of the junction box to increase the integrity of the wireless communications signal. In accordance with an embodiment of the present invention, exemplary hardware for use as WiFi antenna 114 is the Flavus 2.4/5 GHz by Antenova.

Temperature sensor 134 of PCB assembly 100 measures the temperature of the solar in which the solar panel monitoring device is installed. As the temperature of a solar panel increases, the output power of the solar panel is expected to decrease. Thus, when monitoring the power output of a solar panel, it is also helpful to monitor the temperature of the solar panel to ensure that any observed decrease in output is not a result of malfunctioning hardware, or another event requiring immediate maintenance or attention, but is instead due to characteristics inherent to photovoltaic cells. Further, where solar panel installations may include a cooling apparatus, a rise in temperature may indicate that the cooling hardware has failed, and that less power can be expected generated.

Analog to digital converter (ADC) 128 operates to convert analog signals received from sensors on PCB assembly 100 into digital signals for storage in flash memory 130, in accordance with an embodiment of the present invention. ADC 128 is shown coupled to positive bus bar 102, negative bus bar 104, flash memory 130, temperature sensor 134, current sensor 136, and voltage sensor 138. In accordance with an embodiment of the present invention, ADC 128 converts the analog signal it receives from temperature sensor 134, current sensor 136, and voltage sensor 138 to a digital signal for storage in flash memory 130. In accordance with an embodiment of the present invention, ADC 128 may receive signal from each of sensors 134-138 serially, or one at a time. In an alternative embodiment of the present invention, PCB assembly 100 of the solar panel monitoring device includes an ADC 128 for each of the analog sensors. In other words, there may be an ADC optimally configured for receiving signal(s) from temperature sensor 134, an ADC optimally configured for receiving signal(s) from current sensor 136, and an ADC optimally configured for receiving signal(s) from voltage sensor 138. Each optimally configured ADC may have different characteristics.

Processor 106 coordinates receiving information from the various sensors of the monitoring device's PCB assembly 100, and reporting the information to a base station or server through WiFi chip 122, in accordance with an embodiment of the present invention. Processor 106 is shown coupled to flash memory 130, NVRAM 132, and data collector chip 124. Processor 106 is also shown coupled to bus bars 102 and 104 for supplying processor 106′s operating current. Processor 106 receives information from the voltage sensor 138, current sensor 136, and temperature sensor 134 through flash memory 130, which is coupled to ADC 128. In alternative embodiments of the present invention, processor 106 is coupled to multiple ADCs and/or multiple flash memories.

In accordance with an embodiment of the present invention, non-volatile random access memory (NVRAM) 132 stores the program algorithm for processor 106, and directs the transfer of data, sampling pulses, and encryption of data performed by processor 106. NVRAM 132 is shown coupled to positive bus bar 102, ground 104, and processor 106.

Processor 106 executes a program (or software) stored within the program area of NVRAM 132, in accordance with an embodiment of the present invention. Processor 106 may function as follows: it first processes the voltage readings from voltage sensor 138; then, second, it processes the current readings from current sensor 136; then, third, it processes the temperature readings from temperature sensor 134; and then, finally, it processes the GPS readings from the GPS chip 126. Proceeding through these inputs in such an order is provided merely as an example, and processor 106 is operative to process the device's sensors' readings in any workable order.

In accordance with an embodiment of the present invention, the operations of processor 106 are timed and sequenced by crystal oscillator 140. Crystal oscillator 140 also clocks, in addition to processor 106, GPS chip 126, data collector chip 124, and WiFi chip 122. The clock pulse generated by crystal oscillator 140 determines the frequency and timing of data transfer between these chips. In accordance with an embodiment of the present invention, crystal oscillator 140 coordinates the devices on PCB assembly 100 in 30-second cycles. In other words, the temperature, current, voltage, and GPS position are each read, and transmitted once per 30-second interval. Included in each cycle may also be additional or other sensor-provided readings, or information. In situations where more active feedback is desired, crystal oscillator 140 is operative to run shorter cycles, for example every 5 seconds; and where power is to be conserved, crystal oscillator 140 operates in longer cycles, for example every two minutes.

In accordance with an embodiment of the present invention, processor 106 reads the data stored in flash memory 130, depending upon the clock cycle, and then forwards the read data to data collector chip 124. Once data collector chip 124 has received all the data read from flash memory 130 by processor 106, processor 106 instructs data collector chip 124 to forward the data to WiFi chip 122. Once WiFi chip 122 has received the forwarded data from data collector chip 124, processor 106 instructs WiFi chip 122 to transmit the received data via WiFi antenna 114. WiFi chip 122, through WiFi antenna 114, transmits the data to an access point, remote base station, or server. This completes one clock cycle, and then the processor repeats the same sequence of events for subsequent clock cycles, with new information being stored in flash memory 130.

In accordance with an embodiment of the present invention, the cycle time of crystal oscillator 140, processor 106, WiFi chip 122, data collector chip 124, GPS chip 126, and sensors 134, 136, and 138 are all dynamically configurable from base station or by a controlling device. That is, more specifically, the sampling time of sensors 134, 136, and 138, or the reporting rate of processor 106 or WiFi chip 122 is not static, or hard-coded into the devices, and are reprogrammable via remote access. For example, where temperature sensor 209 has already been configured to transmit readings at 30-second intervals, it is then reprogrammed to transmit readings at 5-minute intervals for the purpose of saving power.

Solar panels, as used herein, are any type of solar panels. One such type, readily known to those of ordinary skill in the art is a Photo Voltaic (PV) solar panel.

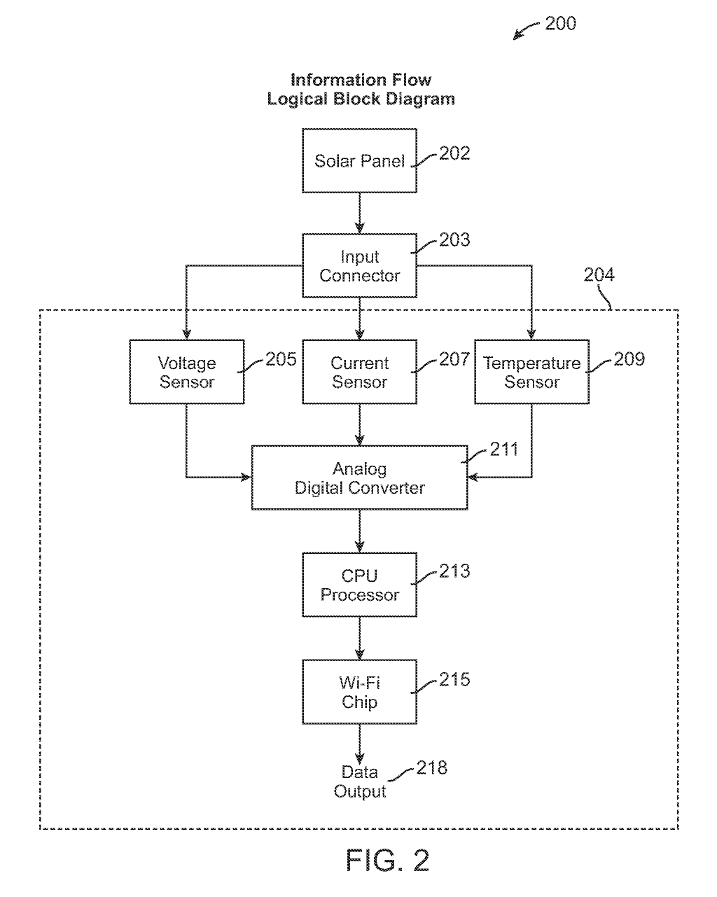

Referring now to FIG. 2, flow diagram 200 shows the process of solar panel information collection and reporting, in accordance with a method of the present invention.

Solar panel 202 provides the status information to, and the power for driving, the solar panel monitoring device 204. When in sunlight, photovoltaic cells of solar panel 202 generate electricity, which is routed to input connector 203. In addition to being received by input connector 203, the power generated by solar panel 202 can also be directed to a junction box, or other connection system for connecting solar panels in series, and then in parallel at a combiner and/or a super-combiner, for delivering power to a central source, from where the power may then be distributed.

As shown in FIG. 2, in an embodiment of the present invention, input connector 203 is the primary interface between solar panel 202 and the solar panel monitoring device 204. Input connector 203 splits the input from solar panel 202, and then forwards the same to voltage sensor 205, current sensor 207, and temperature sensor 209.

In accordance with an embodiment of the present invention, voltage sensor 205 reads the voltage of the electric current passed to it by the input connector 203. Voltage sensor 205 is identical to voltage sensor 138, as discussed above in reference to FIG. 1. Voltage sensor 205 is configured to transmit readings at a predefined interval, such as, for example, every 30 seconds.

In accordance with an embodiment of the present invention, current sensor 207 reads the current of the electric current passed to it by the input connector 203. Current sensor 207 is identical to current sensor 136, as discussed above in reference to FIG. 1. Current sensor 207 is configured to transmit readings at a predefined interval, such as, for example, every 30 seconds.

In accordance with an embodiment of the present invention, temperature sensor 209, powered by the current from input connector 203, reads the temperature of the solar panel 202. Temperature sensor 209 is identical to temperature sensor 134, as discussed above in reference to FIG. 1. Temperature sensor 209 is configured to transmit readings at a predefined interval, such as, for example, every 30 seconds.

As shown in FIG. 2, voltage sensor 205, current sensor 207, and temperature sensor 209 can all make the respective readings in parallel. In other words, voltage sensor 205, current sensor 207, and temperature sensor 209 concurrently provide voltage, current, and temperature values. The benefits of such a configuration are readily apparent when all three variables are interdependent, and it is a purpose of the invention to monitor and track the health and power output of solar panel 202.

In accordance with an embodiment of the present invention, voltage sensor 205, current sensor 207, and temperature sensor 209 all generate analog signals responsive their respective measured values. The analog output is received by analog to digital converter (ADC) 211, which converts the received signals to a discrete digital representation. ADC 211 is identical to ADC 128 of FIG. 1. In the solar panel monitoring device 204 of FIG. 2, only one ADC 211 is used, wherein ADC 211 cycles through receiving input signal from voltage sensor 205, current sensor 207, and temperature sensor 209 in a predefined sequence. In accordance with an alternative embodiment of the present invention, multiple analog to digital converters may be used, wherein each of the voltage sensor 205, current sensor 207, and temperature sensor 209 are configured to send analog signals to a unique ADC.

Upon conversion of the received analog signal to a discrete digital representation by ADC 211, ADC 211 sends the generated digital signal to processor 213, in accordance with an embodiment of the present invention. Processor 213 is identical to processor 106, as discussed above in reference to FIG. 1. Processor 213 receives information relating to solar panel 202, through ADC 211 and as reported by sensors 205-209, and depending upon the content of that information can take certain actions. For example, processor 213 may be configured to verify that the voltage, current, and temperature of solar 202 are within acceptable ranges. If the values are measured to be in-range, then the processor may simply pass the information on for transmission. If, however, the voltage, current, or temperature of solar panel 202 are outside of the acceptable ranges, then processor 213 can take additional steps.

For example, in response to out-of-range readings, processor 213 includes a flag, or alarm condition, in the data passed on to WiFi chip 215. Depending on how far out-of-range any given reading is, processor 213 can flag the reading as more or less serious. Further, processor 213 compares a reading to previous readings of the same sensor. For example, as the sun sets, the power generated by solar panel 202 is expected to drop, as is the temperature. For this reason, a slow, steady decrease in power occurring late each day is to be expected, and is not necessarily an alarm condition.

In accordance with an embodiment of the present invention, processor 213 is also responsive to commands received for solar panel monitoring device 204 by WiFi chip 215. WiFi chip 215 receives communications commanding that solar panel 202, monitoring device 204, or both, be shut off.

In accordance with an embodiment of the present invention, WiFi chip 215 receives data from processor 213, packetizes, and then transmits that data 218 to a receiving base station or server. Information received from processor 213 and transmitted by WiFi chip 215 as data output 218 includes voltage, current, and/or temperature readings, as well as any additional alarm conditions or information included by processor 213. WiFi chip 215 also receives data from a transmitting base station or server, decrypts and decodes as needed, and then forwards the received information to processor 213. In one embodiment of the present invention, WiFi chip 215 is identical to WiFi chip 122, as discussed above in reference to FIG. 1.

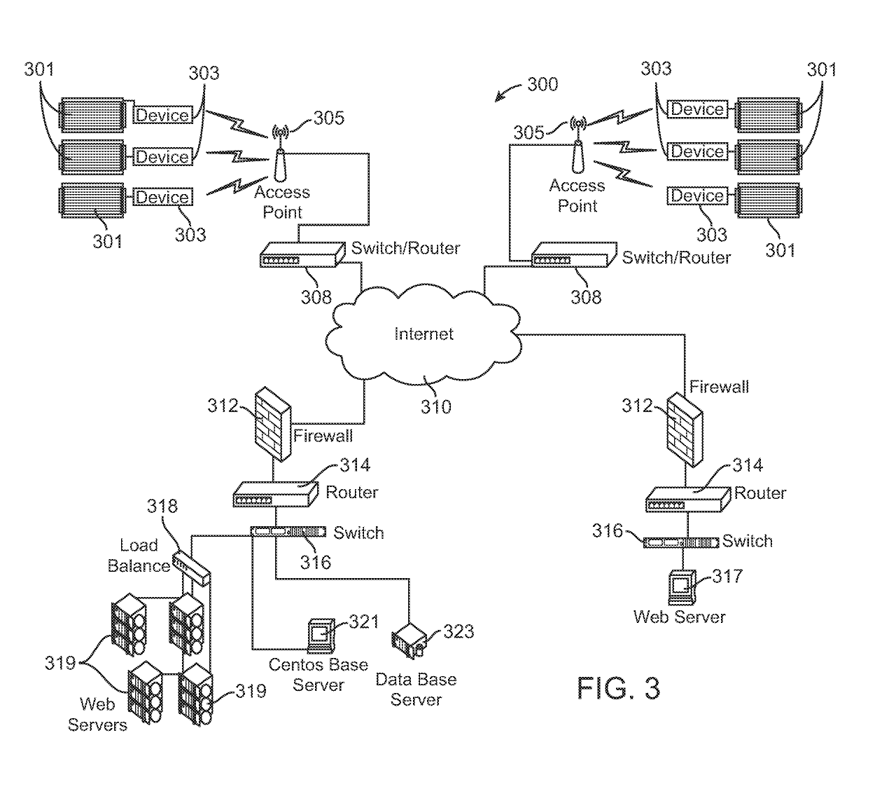

Referring now to FIG. 3, a network map 300 shows how the solar panel monitoring device 303 of the present invention may be used to monitor, measure, manage and report solar panel 301 status and output. In one embodiment of the present invention, solar panel 301 is a Photo Voltaic solar panel. In other embodiments, the solar panel 301 may be solar panels that use minors to generate heat. These types of solar panels reflect the sun's rays using minors, which are used to heat water.

Solar panels 301 can be installed and configured in any of the numerous configurations used for small- to large- scale solar panel installations. For example, solar panels 301 may be mounted on the roof of a home, or solar panels 301 are nodes of an array that includes thousands of individual solar panels.

In accordance with an embodiment of the present invention, a solar panel monitoring device 303 is installed in each solar panel 301. The solar panel monitoring devices 303 are installed within the junction boxes of each solar panel 301, or externally mounted in close proximity to the junction box where the monitoring devices 303 are able to successfully transmit and receive wireless signal, as well as remain protected from inclement weather.

In accordance with an embodiment of the present invention, solar panel monitoring devices 303 actively monitor the voltage, current, temperature, and global position of the solar panels 301 in which the monitoring devices 303 are installed. Solar panel monitoring devices 303 transmit the voltage, current, temperature, and global positioning information, of the solar panels 301 in which the monitoring devices 303 are installed, to access points 305. Solar panel monitoring devices 303 can also transmit other information, as generated by additional sensors, to access points 305. In accordance with an embodiment of the present invention, solar panel monitoring devices 303 transmit this information to access points 305 wirelessly, using a standard such as, for example, the IEEE 802.11a standard. Other standards that may be employed are the IEEE 802.11b, 802.11g or 802.11a. The use of access points 305 and wireless communication from solar panel monitoring devices 303 reduces the costs associated with typical Ethernet communications.

It is contemplated that a single access point 305, with solar panel monitoring devices 303 communicating over the 802.11b/g/a standard, should have the bandwidth and scalability to concurrently monitor up to 1024 solar panel monitoring devices 303, and thus 1024 solar panels 301. The advantages of such a configuration becomes readily apparent when one considers that a solar panel array of 6,000 panels would only require 10 access points 305 for receiving and monitoring the output and status of all 6,000 solar panel monitoring devices 303 attached to the panels.

In accordance with an embodiment of the present invention, access points 305 are hard-wired to a switch or router 308, and connected, through the switch or router 308, to the Internet 310. Multiple access points 305 are connected at a single switch or router 308, which is then connected to Internet 310. Alternatively, access points 305 hard-wired to a switch or router 308, and connected, through the switch or router 308, to a localized intranet. In alternative embodiments of the present invention, access points 305 communicate wirelessly to switch or router 308. Using the Internet 310, or a localized intranet, the solar panel monitoring information (voltage, current, temperature, global positioning, etc.) for each solar panel is transmitted to a remote location. The solar panel monitoring information may pass through firewalls 310, routers 314, switches 316, or load balancers 318 before arriving at a remote server or computer.

In accordance with an embodiment of the present invention, at the remote location, the solar panel monitoring information is manipulated, analyzed, and recorded in an almost limitless number of ways. The monitoring information is kept on a database server 323, where computer clients can compare energy production over time, or in relation to time, weather, temperature, and many other variables. It is contemplated that any authorized network connected device, such as CentOS base server 321, may access and view solar panel monitoring information. Web servers 319 and 317 allow a computer client to access the information using a browser-based interface, or a proprietary interface (e.g., locally installed software) can similarly be used. Web servers 319 and 317 provide guidance for manipulating or searching solar panel monitoring data, such as with simplified graphical interfaces, pre-populated forms, or by guided Boolean search restrictions. Such guidance facilitates viewing commonly or regularly monitored trends, such as, for example, power output over the course of a day, or for power output over a longer period of time, with an adjustment for daily weather patterns.

In accordance with an embodiment of the present invention, each device 303 is equipped with the ability to cease operation of, or disconnect, the solar panel 301 to which it is connected. Disconnection, otherwise known as “bypass,” is necessary, for example, when it is observed that a solar panel 301 is a drain, rather a source of power generation, on other solar panels 301 to which it is attached by a direct connection, junction box, combiner, super-combiner, or otherwise. This can occur where, for example, a solar panel 301 is shorted, damaged by weather such as hail, or damaged by an animal. Other incidents may occur which cause a solar panel 301 to act as a drain rather than a source of power generation for the solar panel array.

In accordance with an embodiment of the present invention, a solar panel 301 is identified as a drain on the solar array by automatic analytical algorithms executed on a webserver 317 or 319, database server 323, CentOS base server 321, or other device. A solar panel 301 can be identified as a drain due to a rapid or instantaneous drop in its power output, contemporaneous with a markedly lower power output by the other solar panels to which it is attached. While the solar panel monitoring device of the present invention facilitates quick identification of a malfunctioning or poorly performing solar panel in a large solar panel array, it is not always possible to quickly fix the issue or to mitigate any ill effects the solar panel may cause.

When a solar panel 301 is identified as a drain on the array by any of the servers 317-323, or other networked device, a bypass command can be sent to the solar panel monitoring device 303 installed in the solar panel 301 identified as a drain. The solar panel monitoring device 303 receiving a bypass command then removes the solar panel 301 which it is monitoring off of the array. In one embodiment, the solar panel monitoring device 303 further acts to reconnect the remaining solar panels to adjacent solar panels. If the servers 317-323, or other networked devices, fail to observe the return of power expected lost due to the drain, the solar panel 301 previously identified as a drain can be brought back online, and/or additional solar panels 301 can be further identified as drains. This entire process may be automated and occur rapidly, with little or no human-operator input. Alternatively, the identification of a drain and issuance of a bypass command requires human-operator verification.

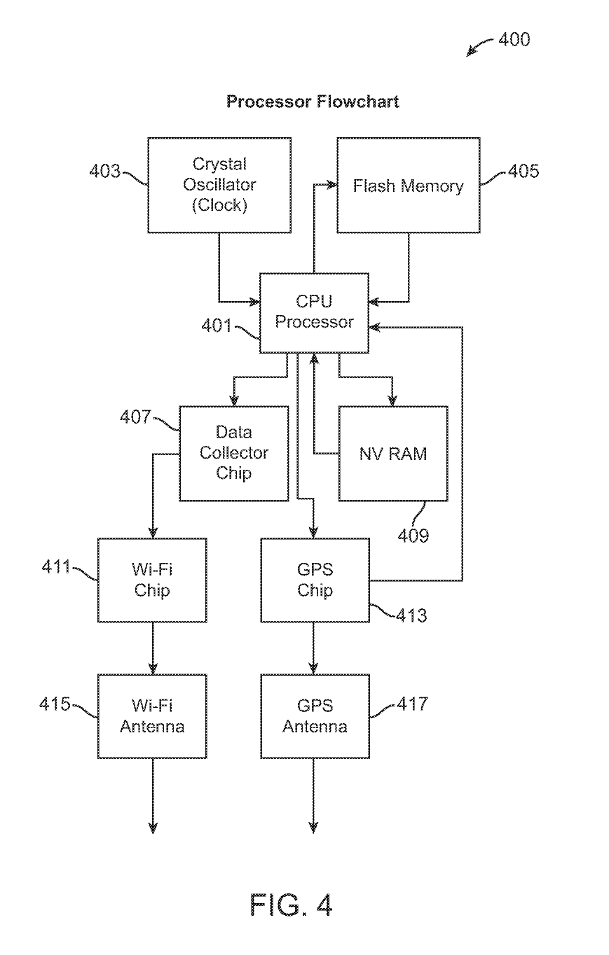

Referring now to FIG. 4 a flow diagram 400 of the steps of the high-level blocks of the present invention shown in communication with each other is disclosed, in accordance with an embodiment of the present invention. As shown in diagram 400 of FIG. 4, processor 401 is directly connected with crystal oscillator 403, flash memory 405, data collector chip 407, NVRAM 409, and GPS chip 413. GPS chip 413 is directly connected to GPS antenna 417. WiFi chip 411 is directly connected to data collector chip 407 and WiFi antenna 415.

Crystal oscillator 403 times and sequences the operations of processor 401. As directed by crystal oscillator 403, processor 403 reads instructions from NVRAM 409 for accessing flash memory 405 or GPS chip 413, and then forwards the accessed information to data collector chip 407. Processor 403 accesses flash memory 405 and retrieves values previously stored by other devices. The values stored in flash memory 405 can be information stored directly or indirectly from a sensor of the monitoring device. Such sensors include temperature sensors, current sensors, voltage sensors, accelerometers, or any other sensor for providing information relating to the atmospheric conditions in which the solar panel is operating, the operational status of the solar panel itself, or any other relevant information. In an alternative embodiment of the present invention, processor 401 obtains values from a sensor or chip directly, instead of accessing flash memory 405, such as information from GPS chip 413.

GPS chip 413, through GPS antenna 417 receives GPS signals from GPS satellites. From the received signals, GPS chip 413 is operative to determine the global coordinates of the GPS panel in which the solar panel monitoring device is installed. After the coordinates have been determined, the GPS chip then forwards this data to processor 401. Processor 401 regularly cycles between obtaining data from flash memory 405 and other components, such as GPS chip 413, directly.

As processor 401 accesses or receives data, it passes the accessed or received data to data collector chip 407. Data collector chip 407 then passes on received information to WiFi chip 411. In accordance with an embodiment of the present invention, data collector chip 407 removes previously stored information after it has forwarded the information to WiFi chip 411. In alternative embodiments, it allows processor 401 to repeatedly rewrite the contents of data collector chip 407.

Through WiFi antenna 415, WiFi chip 411 transmits any or all information received from data collector chip 407. WiFi chip 411 is operative to transmit packets of solar panel information in a number of ways. For example, WiFi chip 411 can steadily and continuously transmits solar panel information; or, alternatively, it may collect information over a period of time, e.g., 30 seconds, and then send all information together, as a burst. Other transmission frequencies by WiFi chip 411 are contemplated, where the monitoring device's power usage is balanced with the regularity and comprehensiveness of the information reported. For example, processor 401 is configured to cause WiFi chip 411 to only transmit solar panel information when a change has occurred, or there is an alarm condition. In other words, processor 401 only forwards data to data collector chip 407, for subsequent transmission by WiFi chip 411, after processor 401 has determined that a substantial drop in power output has occurred.

Modifications can be made to the embodiments of the present invention described above without departing from the broad inventive concept thereof. Having described the preferred embodiments of the invention, additional embodiments, adaptations, variations, modifications and equivalent arrangements will be apparent to those skilled in the art. These and other embodiments will be understood to be within the scope of the appended claims and apparent to those skilled in the art.

What is claimed is:

1. A solar panel monitoring device comprising:
a solar panel monitoring device operative to monitor a solar panel;
a power input, coupled to the output of the solar panel;
at least one sensor coupled to the power input, the at least one sensor adapted to responsively generate monitoring information on the power input;
a processor operative to receive the monitoring information on the power input from each of the at least one sensors, and adapted to forward the received monitoring information;
a transmission chip operative to receive the forwarded monitoring information, to packetize the monitoring information, and to transmit the packetized monitoring information to a remote location; and
a rechargeable battery coupled to the power input,
wherein the rechargeable battery is adapted to be charged by the power input when current is being generated by the solar panel, and is further adapted to power the at least one sensor, processor, and transmission chip when the current of the power input drops below a predetermined threshold value.

2. The solar panel monitoring device of claim 1, wherein the monitoring information received by the transmission chip is received from the processor.

3. The solar panel monitoring device of claim 1, wherein the at least one sensor is operative to monitor the voltage of the power input.

4. The solar panel monitoring device of claim 1, wherein the at least one sensor is operative to monitor the current of the power input.

5. The solar panel monitoring device of claim 1, wherein two sensors are coupled to the power input, a first of the two sensors being operative to monitor the voltage of the power input, and the second of the two sensors being operative to monitor the current of the power input.

6. The solar panel monitoring device of claim 5, further including a fourth sensor operative to monitor the ambient temperature where the solar panel monitoring device is installed.

7. The solar panel monitoring device of claim 6, wherein the transmission chip transmits to a remote location using over-the-air modulation.

8. The solar panel monitoring device of claim 7, wherein the over-the-air modulation is in accordance with any one of the IEEE 802.11 protocols.

9. The solar panel monitoring device of claim 1, wherein the transmission chip is further adapted to receive communications from a remote location.

10. The solar panel monitoring device of claim 9, wherein the communications received by the transmission chip alter the operation of the solar panel monitoring device.

11. A method of monitoring the status of a solar panel comprising:
receiving input from the solar panel, the input being the electricity generated by the solar panel;
sensing the voltage of the input;
sensing the current of the input;
converting the sensed voltage into a first digital value;
converting the sensed current into a second digital value;
transmitting the first digital value; and
transmitting the second digital value.

12. The method of monitoring the status of a solar panel of claim 10, wherein transmitting wirelessly the first digital value and second digital value.

13. The method of monitoring the status of a solar panel of claim 10, further storing the first digital value.

14. The method of monitoring the status of a solar panel of claim 13, further storing the second digital value.

15. The method of monitoring the status of a solar panel of claim 10, further sensing the ambient temperature of the solar panel being monitored, converting the sensed ambient temperature into a third digital value, and transmitting the third digital value.
